(19) United States
(12) Patent Application Publication
(10) Pub. No.: US 2007/0037068 A1
(43) Pub. Date: Feb. 15, 2007

(54) Barrier coating compositions for photoresist and methods of forming photoresist patterns using the same

(75) Inventors: Sang-Jun Choi, Seoul (KR); Mitsuhiro Hata, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/447,896

(22) Filed: Jun. 7, 2006

(30) Foreign Application Priority Data
Aug. 12, 2005 (KR) 10-2005-0074482

(51) Int. Cl. G03F 1/00

(52) U.S. Cl. 430/5

(57) ABSTRACT

Provided are barrier polymers, barrier coating compositions incorporating such polymers and methods for utilizing such barrier coating compositions for suppressing dissolution of photoresist components during immersion photolithography. The barrier polymers may be synthesized from one or more monomers including at least one monomer having a tris(trimethylsiloxy)silyl group and will have a weight average molecular weight (Mw) of 5,000 to 200,000 daltons. The barrier polymer(s) may be combined with one or more organic solvents to form a barrier coating composition that can be applied to a photoresist layer to form a barrier coating layer sufficient to suppress dissolution of components such as PAG into an immersion liquid during exposure processing. The tris(trimethylsiloxy)silyl group monomer(s) may be combined with other monomers, particularly monomers including a polar group, for modifying the hydrophobicity and/or solubility of the resulting barrier coating layer in, for example, a developing solution.

### PRIORITY STATEMENT

This application claims priority under 35 U.S.C. § 119 from Korean Patent Application No. 10-2005-0074482, which was filed on Aug. 12, 2005, in the Korean Intellectual Property Office, the disclosure of which is incorporated herein, in its entirety, by reference.

### BACKGROUND OF THE INVENTION

1. Field of the Invention

Embodiments of the invention include polymeric compounds, and compositions including such compounds, that may be used in forming top coating or barrier coating layers for protecting underlying photoresist compositions and methods of utilizing such compounds and compositions. For example, compounds and compositions according to example embodiments of the invention may be used in manufacturing semiconductor integrated circuits, particularly with respect to methods for forming photoresist layers and patterns having a top coating or barrier coating layer that will improve the performance of the photoresist during, for example, immersion photolithography.

2. Description of the Related Art

During the fabrication of highly integrated semiconductor devices, photolithographic processes are used repeatedly to form a wide variety of patterns that are then utilized, for example, as masks for subsequent etching or ion-implant processes. The smallest lines and spaces that can be formed using a particular photolithographic process are limited, to some degree, by factors such as the wavelength of the light used to expose the pattern, the imaging system used to project the pattern onto the photoresist and the properties of the photoresist composition. For example, line patterns on the order of about 60 nm may represent a lower limit to the patterns that can be produced using a conventional ArF laser (193 nm) light source.

Immersion photolithography processes have been suggested as alternatives to the conventional lithographic processes that can overcome the wavelength limitations associated with the conventional use of ArF laser light sources. In immersion photolithography processes, the gap or space formed between a lens and the wafer surface is filled with liquid that enhances the system performance.

In lithography processes, the numeral aperture (NA) of an exposure system can be calculated from the equation:
NA=n Sin(α)
in which n is the refractive index (RI) of an immersion medium and α is the angle between the optical axis of the system and light entering an objective lens farthest from the optical axis. In general, a larger NA and/or a light source having a shorter wavelength will tend to improve the resolution that can be obtained by the imaging system. Because the immersion medium used in immersion photolithography tends to increase the NA to a value greater than 1, for example, achieving NA values greater than or equal to 1.3, the resolution of the system can be increased. In particular, when H₂O is used as the immersion medium, improved pattern resolution and/or improved depth of focus (DOF) can be achieved when compared with a conventional “dry” photolithographic process by utilizing the refractive index, n, 1.44 of water.

However, using H₂O as an immersion liquid can lead to several problems including, for example, the tendency of photoresist components such as photoacid generators (PAG) and/or bases to leach into water from the photoresist, thereby compromising the performance of the photoresist and/or contaminating the lens. One method for addressing this problem involves forming a top coating or barrier coating layer on the photoresist as disclosed in, for example, by R. R. Dammel et al. in J. Photopol. Sci. Tech., 587, 4 (2004), the disclosure of which is hereby incorporated, in its entirety, by reference. The barrier coating layer prevents or reduces contact between the immersion medium and the photoresist, thus preventing or reducing the likelihood that one or more of the photoresist components will be leached from the photoresist layer.

The barrier coating compositions for use in immersion photolithography processes should exhibit relatively low solubility in the immersion medium for at least the duration of the exposure process, exhibit relatively low absorbance at the wavelength of the exposure light source, exhibit relatively good solubility in a removing solution or developing solution after being exposed, and should exhibit no more than minor intermixing with the photoresist layer to which it is applied.

### SUMMARY OF THE INVENTION

Example embodiments of the invention include barrier coating compositions that exhibit reduced aqueous solubility, exhibit little, if any, intermixing with photoresist compositions when applied to the surface of a photoresist layer, exhibit relatively low absorbance at the UV wavelengths used for exposing the photoresist layer and are readily soluble in developing solutions or another removing solution, for example, one or more aqueous alkaline solutions, after being exposed during an immersion photolithography process. As used herein, readily soluble includes materials that can be substantially completely removed from the surface of the substrate during a developing operation that includes exposing the material layer to a conventional removing solution or developing solution, for example, water or an aqueous alkaline solution of 2.38 wt % TMAH, for a relatively brief period, for example 30 to 60 seconds. As will be appreciated by those skilled in the art, however, a number of variables, for example, the thickness of the layer, previous heat treatment of the layer, the temperature of the developing solution and/or the application rate of the developing solution may affect the rate at which the material is removed from the substrate and, consequently, the development time required for complete removal.

Example embodiments of the invention also include methods of forming a photoresist layer protected by a barrier coating layer suitable for use in immersion photolithography processes.

Example embodiments of the invention include barrier coating compositions having one or more polymers that include a tris(trimethylsiloxy)silyl group as first repeating unit or monomer, the polymer(s) having a weight average molecular weight (Mw) of 5,000 to 200,000 daltons, for example, a weight average molecular weight (Mw) of 10,000 to 30,000, and an organic solvent. The polymers may also be characterized by a polydispersity of no greater than 3, but polymers having higher degrees of polydispersity may still exhibit satisfactory performance.

The first monomer may be expressed by the formula: 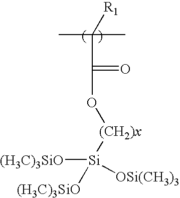
where R₁ is hydrogen or a methyl group, and x is an integer from 2 to 6.

Example embodiments of polymers according to the invention may also include a second repeating unit or monomer that includes a polar group selected from a group consisting of alcohol groups and acid groups, for example, an acid anhydride. Example embodiments of a polymer according to the invention including both first and second monomers may be expressed by the formula: 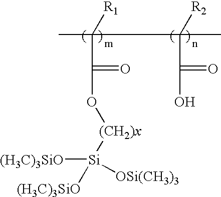
where R₁ and R₂ are independently selected from hydrogen and a methyl group; x is an integer from 2 to 6; m+n=1; and 0.1≦m/(m+n)≦0.9.

Example embodiments of polymers according to the invention may also include both a second monomer having a polar group and a third monomer, for example, an acrylate or methacrylate monomer. Example embodiments of polymers according to the invention including first, second and third monomers may be expressed by the formula: 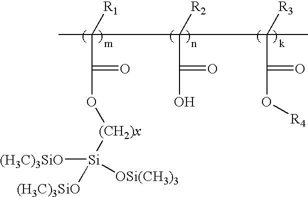
wherein R₁, R₂ and R₃ are independently selected from hydrogen and a methyl group; R₄ is selected from a group consisting of C₁ to C₁₀ alkyl, alcohol, aldehyde, acid, and amino groups; x is an integer from 2 to 6; and the expressions m+n+k=1; 0.1≦m/(m+n+k)≦0.8; 0.1≦n/(m+n+k)≦0.8; and 0.1≦k/(m+n+k)≦0.8 are satisfied.

The organic solvent may be, for example, an alcohol-based organic solvent, an alkane-based organic solvent or a combination thereof. Example embodiments of the organic solvent include C₃ to C₁₀ alcohol-based organic solvents, C₄ to C₁₂ alkane-based organic solvents, as well as combination, blends and mixtures thereof.

Example embodiments of the invention also include methods of forming photoresist patterns that may include: forming a photoresist layer on a substrate; soft-baking the photoresist layer at a first temperature; forming a barrier coating layer on the soft-baked photoresist layer using a barrier coating composition which includes a polymer having a weight average molecular weight (Mw) of 5,000 to 200,000 daltons, for example, from 10,000 to 30,000 daltons, and including a first monomer of a tris(trimethylsiloxy)silyl group which may account for between 30% and 70% of the monomer units of the polymer, and an organic solvent; exposing a predetermined region of the photoresist layer through a liquid medium distributed across the barrier coating layer; post-exposure baking (PEB) the exposed photoresist layer; removing the barrier coating layer; and developing the exposed photoresist layer.

The step of forming the barrier coating layer may include spin-coating the barrier coating composition on the photoresist layer and heat-treating the spin-coated barrier coating composition.

The steps of removing the barrier coating layer and developing the exposed photoresist layer may be performed in a single step using a single developing solution.

Example embodiments of semiconductor fabrication according to the invention include processes in which a barrier coating layer is formed from a composition including one or more polymers having at least one repeating unit or monomer that includes a tris(trimethylsiloxy)silyl group. This barrier coating layer can then be used as a barrier during immersion photolithography to protect the underlying photoresist and prevent or suppress the dissolution of one or more components of the photoresist into the liquid medium. It has been suggested by exposure equipment manufacturers that leaching rates from the photoresist should be below 2.5 ng/cm²/s for PAG compounds and below 1.0 ng/cm²/s for amines in order to maintain acceptable transparency of the lower lens surface.

This barrier coating composition is also selected so that there is little, if any, intermixing of the barrier coating composition and the photoresist during the photolithography process while still exhibiting good solubility in a developing solution, which may also be the developing solution used for developing the photoresist pattern from the exposed photoresist layer. Therefore, the barrier coating compositions and methods of forming a photoresist pattern using an immersion photolithography process according to the invention can improve the resolution of fine patterns, provide improved pattern profiles and/or lower the manufacturing cost by, for example, reducing the material costs and/or by simplifying the fabrication process.

### BRIEF DESCRIPTION OF THE DRAWINGS

The above and other features and advantages of the invention will become more apparent by describing in detail example embodiments thereof with reference to the attached drawings in which:

FIGS. 1A through 1E are sectional views illustrating a method of forming a photoresist pattern according to an example embodiment of the invention;

FIG. 2 shows scanning electron microscopy (SEM) images of line and space (L/S) patterns achieved using various exposure doses using a method according to an example embodiment of the invention; and

FIG. 3 shows SEM images of top and vertical profiles of L/S patterns, according to an embodiment of the invention compared with those of a comparison example.

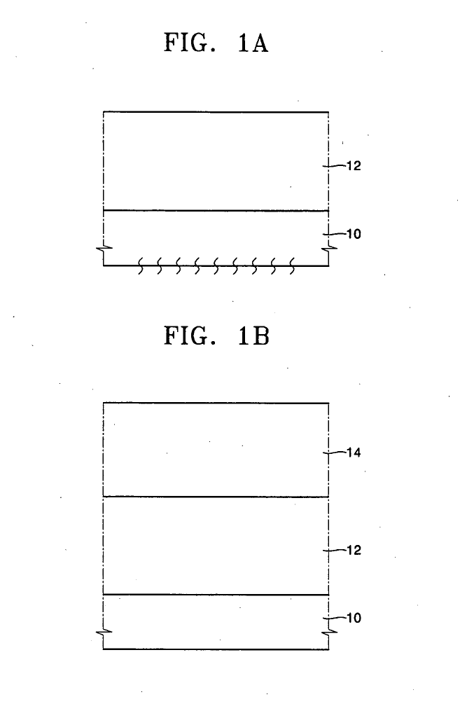

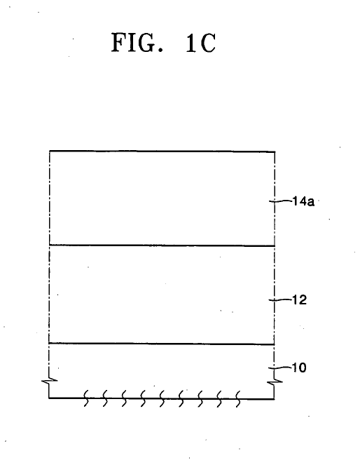

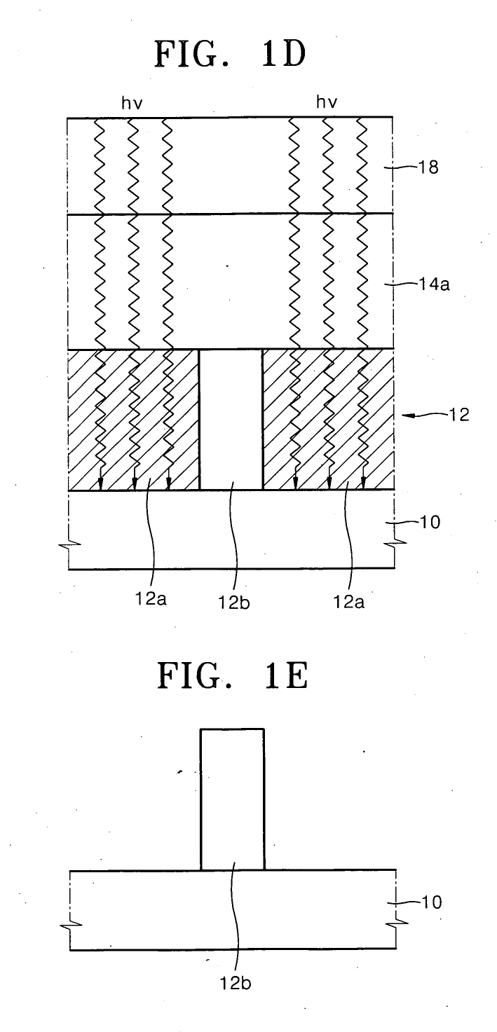

The drawings provided in FIGS. 1A-1E are for illustrative purposes only and are not drawn to scale. The spatial relationships and relative sizing of the elements illustrated in the various embodiments, for example, the various films and layers comprising the semiconductor device may have been reduced, expanded or rearranged to improve the clarity of the figure with respect to the corresponding description. The figures, therefore, should not be interpreted as accurately reflecting the relative sizing, value or positioning of the corresponding structural elements that could be encompassed by actual semiconductor devices manufactured according to the example embodiments of the invention.

### DETAILED DESCRIPTION OF EXAMPLE EMBODIMENTS

Barrier coating compositions according to example embodiments of the invention may be used in forming a barrier coating layer on a photoresist layer that is sufficient to prevent or suppress the leaching of one or more components of the photoresist into an immersion medium applied to the barrier coating layer during immersion photolithography. Barrier coating compositions according to example embodiments of the invention include the combination of one or more polymers having a first monomer that includes a tris(trimethylsiloxy)silyl group and having a weight average molecular weight (Mw) of 5,000 to 200,000 daltons and one or more organic solvents.

The first monomer may be expressed by the formula:

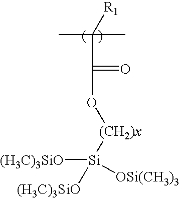

where R₁ is selected from hydrogen and a methyl group and x is an integer from 2 to 6. The alkyl group (CH₂)ₓ acts as a flexible spacer group for the polymer. As will be appreciated by those skilled in the art, each of the “monomers” may, in fact, include a number of the compounds encompassed by the general formula for that monomer. For example, the polymer could include as a first “monomer” a combination of various tris(trimethylsiloxy)silyl group monomers in which the R₁ substituent (H or CH₃) and/or the alkyl chain (CH₂)ₓ are different as suggested in the formula below: 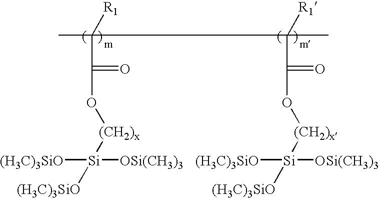
wherein m+m′=1, R₁ and R₁′ can be independently selected from hydrogen and methyl and/or X and X′ can be independently selected from integers from 2 to 6. Those skilled in the art will, accordingly, appreciate that other combinations including a variety of monomers falling within the general formulas illustrated above may comprise the first, second and third “monomers” respectively.

Example embodiments of polymers useful in barrier coating compositions according to the invention may include both a first monomer, as described above, and a second monomer that includes at least one polar group, for example, an alcohol group or an acid group. The second monomer may also comprise an acid anhydride.

The second monomer may be included in the polymer to increase the solubility of the barrier coating layer in an alkaline developing solution, and may include an alcohol group or an acid group, for example, a carboxyl group and/or a sulfonic acid group.

Example embodiments of polymers according to the invention that include both first and second monomers may be expressed by the formula: 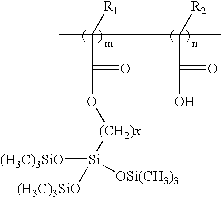
where R₁ and R₂ are independently selected from a group consisting of hydrogen and a methyl group; x is an integer from 2 to 6; and the expressions m+n=1; and 0.1≦m/(m+n)≦0.9 are satisfied. For example, embodiments of polymers according to the invention that the relative prevalence of the monomers particularly includes those polymers in which the tris(trimethylsiloxy)silyl group monomer(s), i.e., the first monomer(s), account for 30% to 70% of the monomer units of the polymer and have a weight average molecular weight of 10,000 to 30,000 daltons.

When the unit ratio between the first and second monomers is 2:1, i.e., m:n=2:1, in the polymer and the second monomer includes an acid group (—COOH), the bulk structure of the tris(trimethylsiloxy)silyl group compared to that of the acid group dominates the volume ratio within the entire polymer. Accordingly, when the immersion photolithography is performed using a barrier coating layer formed from a barrier coating composition including one or more polymers having such a structure, the hydrophobicity required for immersion photolithography is provided in large part by the tris(trimethylsiloxy)silyl group while, conversely, the solubility in alkaline solutions, e.g., a alkaline developing solution, is provided by the acid group (—COOH as illustrated in the polymer structure above) or the alcohol group (not shown) incorporated within the barrier coating layer. Accordingly, a barrier coating layer incorporating such a polymer may be removed in a single step using the same or substantially the same developing solution that will be used to develop the resist pattern from the exposed photoresist layer underlying the barrier coating layer.

Polymers included in the barrier coating composition according to example embodiments of the invention may further include both a second monomer having a polar group and a third monomer comprising, for example, an acrylate or a methacrylate monomer unit. The third monomer can act as a buffer to provide some degree of control over both the hydrophobicity of the polymers resulting from the first monomer and the polarity of the polymer resulting from the second monomer. The composition of the third monomer and its relative presence in the polymers according to the invention may be used for selectively modifying the hydrophobicity and/or polarity of polymers according to the invention.

When polymers in a barrier coating composition according to an example embodiment of the invention include the first monomer, second monomer, and third monomer, the polymer can be expressed by formula: 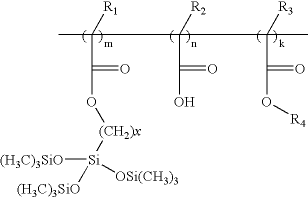
where R₁, R₂ and R₃ are independently selected from a group consisting of hydrogen and a methyl group; R₄ is selected from a group consisting of C₁ to C₁₀ alkyl, alcohol, aldehyde, acid and amino groups; x is an integer from 2 to 6; and the fractional subscripts m, n and k satisfy the expressions: m+n+k=1; 0.1≦m/(m+n+k)≦0.8; 0.1≦n/(m+n+k)≦0.8; and 0.1≦k/(m+n+k)≦0.8.

Barrier coating compositions according to example embodiments of the invention utilize one or more organic solvents for dissolving the polymer(s), and may be selected from a group consisting of alcohol-based organic solvents, alkane-based organic solvents and mixtures, blends and combinations thereof. For example, the alcohol-based solvent(s) may be selected from C₃ to C₁₀ alcohols, the alkane-based solvent(s) may be selected from a group consisting of C₄ to C₁₂ alkanes, and the mixtures, blends and combinations may include one or more of the alcohols and/or alkanes to provide a suitable solvent. For example, the organic solvent may be a C₄ to C₈ alcohol-based organic solvent with a decane cosolvent.

As will be appreciated by those skilled in the art, the selection of an appropriate solvent for a particular polymer or combination of polymers for preparing a barrier coating composition according to the example embodiments of the invention should present no significant difficulty. As will also be appreciated, the solvent system utilized in the barrier coating composition, particularly alcohol-based organic solvents, may include other secondary components, for example, alkanes, nitryls, and/or ethers for modifying the fluid properties and/or performance of the barrier coating composition.

Other components of the barrier coating composition may include viscosity modifiers and/or one or more surfactants selected from a group including fluorine-based surfactants, silicon-based surfactants, anionic surfactants, cationic surfactants and/or non-ionic surfactants for improving the performance of the barrier coating composition with respect to, for example, barrier coating layer uniformity and/or suppressing intermixing with the underlying photoresist during application and/or exposure.

Solvents having little or no polarity are generally considered more suitable for forming the barrier coating composition according to example embodiments of the invention because such solvents will suppress or eliminate intermixing between the barrier coating composition and both water and the underlying resist layer. The solvent may also include C₄ to C₁₂ aliphatic hydrocarbon compounds. If the solvent has substantially no polarity, a coating formed from a composition including such a solvent may exhibit a lack of uniformity or other defects. These defects may be suppressed or eliminated using a solvent system comprising a mixture of one or more C₄ to C₁₂ aliphatic hydrocarbon compounds and one or more C₃ to C₁₀ alcohol-based organic solvents.

The solvent system may include 90 wt % or more of one or more C₄ to C₁₂ aliphatic hydrocarbon compounds based on the total weight of the organic solvent. Alkane-based solvents suitable for use in barrier coating compositions according to example embodiments of the invention include, for example, nonane and decane. Alcohol-based organic solvent suitable for use in barrier coating compositions according to example embodiment of the invention include, for example, isobutanol and 4-methyl-2-pentanol.

When forming a photoresist pattern using the immersion photolithography, a barrier coating layer may be formed on an underlying photoresist layer to provide a barrier coating layer using a barrier coating composition according to example embodiments of the invention. This barrier coating layer is provided to reduce or to prevent the leaching of the photoresist components into the immersion medium, for example, water. An example embodiment of a method of forming a photoresist pattern using the barrier coating composition according to the invention will be described below with reference to FIGS. 1A-1E.

FIGS. 1A-1E are cross-sectional views illustrating an example embodiment of a method for forming a photoresist pattern using immersion photolithography according to the invention. As illustrated in FIG. 1A, a photoresist layer 12 may be formed on a semiconductor substrate 10. The photoresist layer 12 may be formed using a conventional, chemically amplified photoresist composition containing a photo acid generator (PAG). The chemically amplified photoresist composition may, for example, be a photoresist composition designed for exposure using a KrF excimer laser (248 nm), an ArF excimer laser (193 nm), or a F₂ excimer laser (157 nm) light source. In addition, the photoresist used for forming photoresist layer 12 may be a positive photoresist composition or a negative photoresist composition.

After the photoresist layer 12 is formed on the semiconductor substrate 10, the photoresist layer may be subjected to a soft bake at a temperature of about 105° C. to 130° C. to remove a portion of the solvent and harden the photoresist.

As illustrated in FIG. 1B, the soft-baked photoresist layer 12 may then be coated with a barrier coating composition according to an example embodiment of the invention to form a layer 14 of the barrier coating composition. The barrier coating composition may be applied to the substrate by spin-coating the barrier coating composition at, for example, at 500 to 3000 rpm for 30 to 90 second to form the barrier coating composition layer 14.

As will be appreciated by those skilled in the art, the parameters of the spin coating process will depend on a number of factors including, for example, the target thickness of the barrier coating composition 14, the spin rate of the coating assembly, the viscosity of the barrier coating composition, the diameter of the substrate and the volume of the barrier coating composition dispensed onto the surface of the substrate. Those skilled in the art will, for example, be able to select spin-coating parameters of, for example, 1500 to 2500 rpm for 30 to 90 seconds, a range of values that should be generally suitable for achieving a substantially defect-free and sufficiently uniform barrier coating composition layer 14.

As illustrated in FIG. 1C, the barrier coating composition layer 14 may then be heat-treated or cured in some other appropriate manner to form a barrier coating layer 14a. A heat treatment is performed at a temperature between about 95° C. to 120° C. is expected to be suitable for forming the barrier coating composition layer.

As illustrated in FIG. 1D, a portion of the photoresist layer 12 is exposed to light energy passing through the barrier coating layer 14a and a liquid medium 18 provided on the barrier coating layer between the light source, for example, an ArF excimer laser (193 nm), and the photoresist layer. After the exposure, the photoresist layer 12 will comprise an exposed region 12a and a non-exposed region 12b.

The liquid medium 18 may include, for example, water. In this case, the barrier coating layer 14a interposed between the photoresist layer 12 and the liquid medium 18 prevents or suppresses the leaching of photoresist components from the underlying photoresist layer 12 into the liquid medium 18. As will be appreciated, immersion photolithography using an aqueous solution having a pH other than approximately 7 or a non-aqueous solvent as the liquid medium will necessitate the use of a barrier coating layer that is reformulated to be at least relatively insoluble in the liquid medium of choice.

As illustrated in FIG. 1E, the exposed photoresist layer 12 may then be subjected to post-exposure baking (PEB) process after which the barrier coating layer 14a is removed and the exposed photoresist layer 12 is developed. The barrier coating layer 14a formed from a barrier coating composition according to example embodiments of the invention will exhibit much greater solubility in an alkaline developing solution than in water. Accordingly, it is unnecessary to perform a separate process for removing the barrier coating layer 14a before developing the exposed photoresist layer 12 as the barrier coating layer can be removed during the initial stages of the development process. The alkaline developing solution may be, for example, a 2.38% tetramethylamonium hydroxide (TMAH) solution or other conventional developing solution.

During the developing process, the barrier coating layer 14a and the exposed region(s) 12a of the photoresist layer 12 are removed, leaving a photoresist pattern comprising the unexposed region(s) 12b of the photoresist layer 12 on the semiconductor substrate 10. As illustrated, when the photoresist layer 12 is formed from a positive photoresist composition, only the non-exposed region 12b remains on the semiconductor substrate 10, as illustrated in FIG. 1E. However, as will be appreciated by those skilled in the art, if the photoresist layer 12 was formed from a negative photoresist composition, only the exposed region(s) 12a would remain on the semiconductor substrate 10 (not shown) after developing the photoresist pattern.

In addition to the detailed explanation provided above and as illustrated in FIGS. 1A-1E, certain example embodiments and comparative data are provided below to amplify the detailed description and provide certain representative example whereby the scope and application of the invention may be more fully appreciated. As will be appreciated by those skilled in the art, the inventions described herein may be embodied in many different forms and should not be construed as being limited to the example embodiments set forth herein. These embodiments are provided so that this disclosure will provide a thorough and complete description of the inventions and will fully convey the invention to those skilled in the art.

### EXAMPLE 1

### Polymerizing Si-Containing Polymer (1)

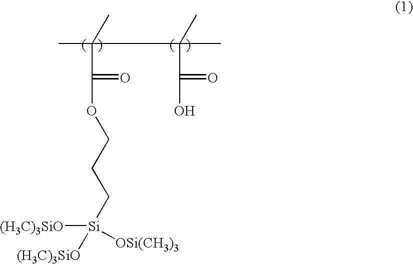

4.3 g (10 mmol) of tris(trimethylsiloxy)silylpropyl methacrylate (obtained from Aldrich Chemical), 0.5 g (5 mmol) of methacrylic acid, and 5 mol % of azobisisobutyronitrile (AIBN) were dissolved in 20 ml of anhydrous THF in a round bottom flask, and then purged using nitrogen gas. The mixture was then polymerized under nitrogen at about 65° C. for 24 hours.

After polymerization, the polymeric material was precipitated in an excess amount of water and filtered. The polymeric retentate was then dried at about 50° C. for about 24 hours in a vacuum oven. The calculated polymerization yield was 70% with the resulting polymeric material exhibited a weight average molecular weight (Mw) of 14,800 daltons and a polydispersity (Mw/Mn) of 1.8.

### EXAMPLE 2

### Polymerizing Si-Containing Polymer (2)

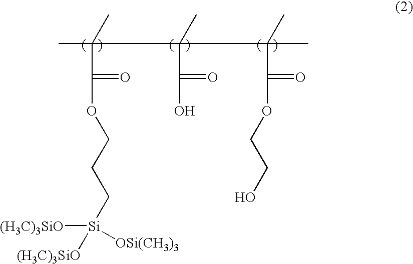

4.3 g (10 mmol) of tris(trimethylsiloxy)silylpropyl methacrylate (obtained from Aldrich Chemical), 0.5 g (3 mmol) of methacrylic acid, and 4.0 g (3 mmol) of 2-hydroxyethylmethacrylate, and 5 mol % of AIBN were dissolved in 35 ml of anhydrous THF in a round bottom flask, and then, purged using nitrogen gas. The mixture was then polymerized under nitrogen at about 65° C. for 24 hours.

After polymerization, the polymerized materials were precipitated in an excess amount of water and then filtered. The polymeric retentate was then dried at about 50° C. for about 24 hours in a vacuum oven. The calculated polymerization yield was 75% with the resulting polymeric material exhibited a weight average molecular weight (Mw) of 12,500 daltons and a polydispersity (Mw/Mn) of 1.8.

### EXAMPLE 3

### Polymerizing Si-Containing Polymer (3)

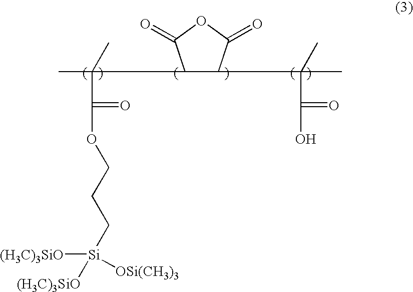

4.3 g (10 mmol) of tris(trimethylsiloxy)silylpropyl methacrylate (obtained from Aldrich Chemical), 1.3 g (13 mmol) of maleic anhydride, and 0.3 g (3 mmol) of methacrylic acid, and 4 mol % of AIBN were dissolved in 10 ml of anhydrous THF in a round bottom flask, and then, purged using nitrogen gas. The mixture was then polymerized under nitrogen at about 65° C. for 24 hours.

After polymerization, the polymerized materials were precipitated in an excess amount of water and filtered. The polymeric retentate was then dried at about 50° C. for about 24 hours in a vacuum oven. The calculated polymerization yield was 45% with the resulting polymeric material exhibiting a weight average molecular weight (Mw) of 8,500 daltons and a polydispersity (Mw/Mn) of 2.0.

### EXAMPLE 4

### Polymerizing Si-Containing Polymer (4)

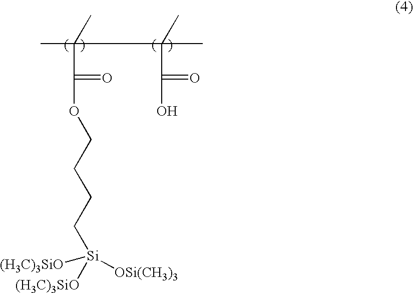 4.4 g (10 mmol) of tris(trimethylsiloxy)silylpropyl methacrylate (obtained from Aldrich Chemical), 0.5 g (5 mmol) of methacrylic acid, and 5 mol % of AIBN were dissolved in 20 ml of anhydrous THF in a round bottom flask, and then, purged using nitrogen gas. The mixture was then polymerized under nitrogen at about 65° C. for 24 hours.

After polymerization, the polymerized materials were precipitated in an excess amount of water and filtered. The polymeric retentate was then dried at about 50° C. for about 24 hours in a vacuum oven. The calculated polymerization yield was 72% with the resulting polymeric material exhibiting a weight average molecular weight (Mw) of 15,500 daltons and a polydispersity (Mw/Mn) of 1.8.

### EXAMPLE 5

### Hydrophobicity of Polymer

Polymers included in the barrier coating composition according to example embodiments of the invention were manufactured using various ratios of a tris(trimethylsiloxy)silylpropyl methacrylate monomer unit (SiMA), a methacrylic acid monomer unit (MA), and a 2-hydroxyethylmethacrylate monomer unit (HEMA). Each of the resulting polymers was then analyzed to determine their hydrophobicity by dissolving the polymers in a 4-methyl-2-pentanol solution to form a series of barrier coating compositions. These barrier coating compositions were then applied to the surface of a substrate to from a barrier coating layer. A water droplet was placed on each of the resulting barrier coating layers, and a static angle and a sliding angle were measured for each composition.

The static angle θ was measured according to a conventional measuring method in which a water droplet is formed on the barrier coating layer and the contact angle of the droplet with respect to the surface of the barrier coating layer was measured. The sliding angle was measured by placing a 50 μl water droplet on a horizontal barrier coating layer surface. The angle at which the substrate was inclined with respect to a horizontal reference plane was then gradually increased from 0° until the water droplet began to move down, i.e., “slide,” the barrier coating layer. The angle at which the trailing edge of the droplet moved 1 mm was recorded as the sliding angle. The results obtained are shown in TABLE 1.

Those of skill in the art will appreciate that sliding angles can also be measured by placing a sized droplet on an inclined plane or, as described above, placing a sized droplet on a horizontal surface that is then slowly inclined. Those skilled in the art will also appreciate that these two methods will tend to produce somewhat different “sliding angles” for the same surface as a result of the hysteresis of the drop, i.e., the difference between the advancing and receding contact angles.

Hydrophobicity results for polymers made of various ratios of a 2-ethyladmantyl acrylate monomer unit (EAdA), an acrylic acid monomer unit (AA), and a 3-hydroxypropyl acrylate monomer unit (HPMA) are also shown in TABLE 1 as comparison examples.

TABLE 1

| | | | Sliding angle |
|---|---|---|---|
| | Ratio (a:b:c) | Static angle (°) | (°) |
| Poly(SiMAₐ-MA_{b}-HEMA_{c}) | 6:2:0 | 103 | 30 |
| | 6:3:0 | 102 | 31 |
| | 6:3:1 | 102 | 38 |
| | 5:3:5 | 98 | 45 |
| Poly(EAdAₐ-AA_{b}-HPMA_{c}) | 8:6:0 | 82 | 58 |
| | 8:5:3 | 80 | 56 |
| | 8:3:5 | 78 | 55 |
| | 8:1:8 | 75 | 50 |

As illustrated in TABLE 1, the example embodiments of Si-containing polymers according to the invention intended for inclusion in example embodiments of barrier coating compositions according to the invention exhibit greater hydrophobicity (higher static angles and lower sliding angles) then the comparative examples. In addition, the Si-containing polymers according to the invention are intended for inclusion in example embodiments of barrier coating compositions that, according to the invention exhibit excellent solubility in an alkaline solvent. These Si-containing polymers are, therefore, rather easily dissolved in typical alcohol group solvents and solvent systems, for example, n-hexane or a mixture of decane and isobutanol (decane:isobutanol=97:3 by weight). Accordingly, barrier coating compositions according to the example embodiments of the invention, when utilized for forming a barrier coating layer to protect photoresist during immersion photolithography will exhibit the desired combinations of hydrophobicity and acceptable solubility in conventional organic solvents, organic solvent systems and conventional alkaline aqueous developing solutions. Barrier coating compositions in accord with the invention can, therefore, be used to protect photoresist during immersion photolithography and maintain or improve imaging performance.

### EXAMPLE 6

### Barrier Characteristics of Barrier Coating Layer

A photoresist layer was formed on a substrate and a barrier layer was formed on the photoresist layer using a barrier coating composition according to an example embodiment of the invention for evaluating the characteristics of the barrier layer. A simulated immersion photolithography exposure process was then conducted by immersing the coated substrates in 25° C. deionized water for 60 seconds, dry-exposing the coated substrates, and then again immersing the coated and exposed substrates in 25° C. deionized water for another 60 seconds. This simulated immersion photolithography exposure process was used for evaluating each of the other examples described below unless different conditions are specifically noted.

An anti-reflective coating (ARC) material (specifically AR 46TM manufactured by Rohm-Hass) intended for an exposure wavelength of 193 nm was spin-coated on an 8-inch bare silicon wafer and then baked to form an ARC layer having a thickness of about 290 Å. A positive photoresist (specifically RHR3640TM manufactured by ShinEstu) intended for an exposure wavelength of 193 nm was spin-coated on the ARC layer, and then baked at 110° C. for 60 seconds to obtain a photoresist layer having a thickness of about 1800 Å.

A barrier coating composition was prepared by dissolving 1 g of the polymer according to Example 1 in 50 g of 4-methyl-2-pentanol to form a solution. This solution was then filtered using a 0.2 μm membrane filter to obtain a barrier coating composition.

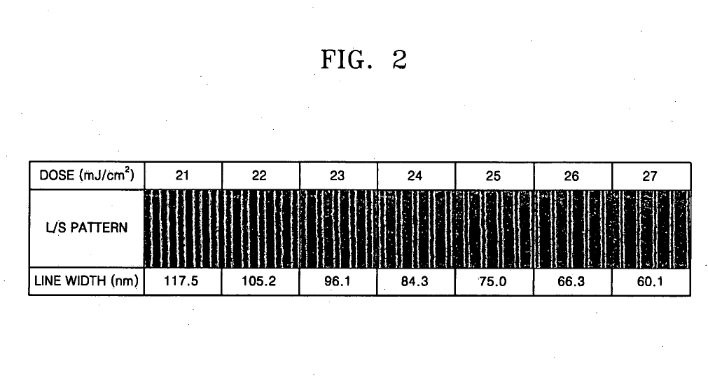

The barrier coating composition was spin-coated at 2000 rpm onto the photoresist layer previously formed on the wafer to form a layer having a thickness of about 400 Å. This barrier coating layer was then heat-treated at about 100° C. for about 60 seconds to form a barrier coating layer. The surface of the wafer was soaked in 25° C. deionized water for 60 seconds, exposed to an ArF excimer laser using an AMSL1100 ArF scanner (NA=0.75 annular and σ=0.85/0.55), soaked in 25° C. deionized water for 60 seconds, subjected to a PEB at 120° C. for 90 seconds, and then developed with a 2.38% tetramethylammonium hydroxide solution for 60 seconds. The resulting photoresist patterns exhibited clean line and space patterns (L/S pattern) having substantially vertical walls and without T-top profiles over a range of exposure doses ranging from 21 to 27 mJ/cm² as illustrated in FIG. 2.

### EXAMPLE 7. COMPARATIVE EXAMPLE

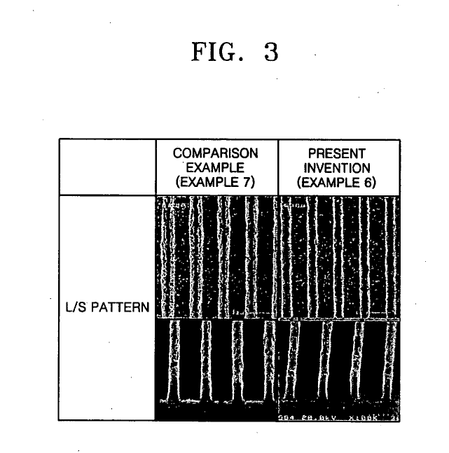

Using the same conditions described above with regard to Example 6, L/S patterns were formed on silicon wafers, with the exception that the polymer composition (EAdAa-AAb-HPMAc) (a:b:c=8:3:5) noted above in TABLE 1 was substituted for the polymer according to an example embodiment of the invention in forming the barrier coating composition. FIG. 3 shows top and vertical profiles of L/S patterns obtained at the exposure dose of 25.2 mJ/cm² using the barrier coating composition of the comparative example (Example 7) and the corresponding L/S patterns obtained using the barrier coating composition according to an example embodiment of the invention (Example 6) obtained with an exposure dose of 24 mJ/cm².

As illustrated in FIG. 3, a clean L/S pattern having a photoresist profile exhibiting vertical or substantially vertical walls without T-tops was obtained by exposing the photoresist layer through a barrier coating layer according to an example embodiment of the invention.

The barrier coating compositions according example embodiments of the invention include a first repeating unit or monomer comprising a tris(trimethylsiloxy)silyl group. A barrier coating layer obtained from the composition according to the invention is used as a barrier during immersion photolithography such that photoresist components are prevented from dissolving in the liquid medium during exposing through the liquid medium, and from the intermixing with the liquid medium during photolithography. The barrier coating barrier formed of the coating composition according to the invention has a good solubility to a developing solution after exposure. Therefore, the method of forming a photoresist pattern by an immersion photolithography process using the barrier coating composition according to the invention can easily form a fine pattern having a good profile and lower the manufacturing cost because of the use of inexpensive materials.

While the invention has been particularly shown and described with reference to example embodiments thereof, it will be understood by those of ordinary skill in the art that various changes in form and details may be made therein without departing from the spirit and scope of the invention as defined by the following claims.

What is claimed is:

1. A barrier coating composition comprising:
a polymer incorporating a plurality of tris(trimethylsiloxy)silyl group monomers and having a weight average molecular weight (Mw) of 5,000 to 200,000 daltons; and
an organic solvent.

2. The barrier coating composition according to claim 1, wherein:
the polymer corresponds to formula I: 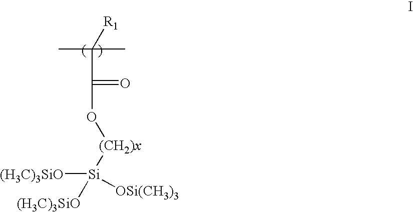
wherein R₁ is selected from a group consisting of hydrogen, methyl and mixtures thereof; and
x is an integer from 2 to 6.

3. The barrier coating composition according to claim 1, wherein:
the polymer incorporates a plurality of second monomers wherein each of the second monomers includes at least one polar group.

4. The barrier coating composition according to claim 1, wherein:
the polymer incorporates a plurality of second monomers wherein a majority of the second monomers includes at least one polar group.

5. The barrier coating composition according to claim 3, wherein:
the polar groups are selected from a group consisting of alcohol groups, acid groups and mixtures thereof.

6. The barrier coating composition according to claim 3, wherein:
the polymer corresponds to formula II: 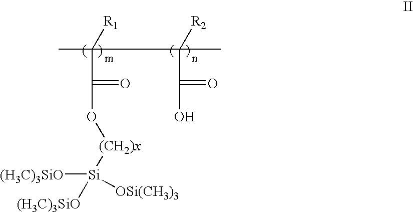
wherein R₁ and R₂ are independently selected from a group consisting of hydrogen, methyl and mixtures thereof;
x is an integer from 2 to 6; and
the expressions (m+n)=1 and 0.1≦(m/(m+n))≦0.9 are satisfied.

7. The barrier coating composition according to claim 3, wherein:
the second monomer is an acid anhydride.

8. The barrier coating composition according to claim 1, wherein the polymer further comprises:
a second monomer including a polar group; and
a third monomer selected from a group consisting of acrylates and methacrylates.

9. The barrier coating composition of claim 8, wherein:
the polymer corresponds to formula III: 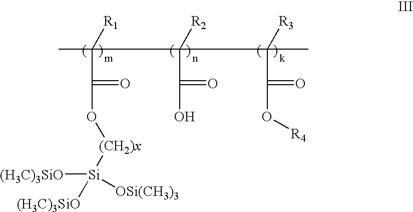
where R₁, R₂ and R₃ are independently selected from a group consisting of hydrogen and methyl;
R₄ is selected from a group consisting of C₁ to C₁₀ alkyl, alcohol, aldehyde, acid and amino groups;
x is an integer from 2 to 6;
and the expressions
(m+n+k)=1;
0.1≦(m/(m+n+k))≦0.8;
0.1≦(n/(m+n+k))≦0.8; and
0.1≦(k/(m+n+k))≦0.8 are satisfied.

10. The barrier coating composition according to claim 9, wherein:
0.3≦(m/(m+n+k))≦0.7; and
the polymer has a weight average molecular weight of 10,000 to 30,000 daltons.

11. The barrier coating composition according to claim 9, wherein:
R₄ is a hydroxyethyl group.

12. The barrier coating composition according to claim 1, wherein:
the organic solvent is selected from a group consisting of alcohol-based organic solvents, alkane-based organic solvents and mixtures thereof.

13. The barrier coating composition according to claim 1, wherein:
the organic solvent is selected from a group consisting of C₃ to C₁₀ alcohol-based organic solvents, C₄ to C₁₂ alkane-based organic solvents and mixtures thereof.

14. The barrier coating composition according to claim 1, wherein:
the organic solvent includes an alcohol-based organic solvent and at least one compound selected from a group consisting of alkanes, nitryls, ethers, surfactants and viscosity modifiers.

15. A method of forming a photoresist pattern comprising:
forming a photoresist layer on a substrate;
forming a barrier coating layer on the photoresist layer with a barrier coating composition incorporating a polymer that includes a plurality of tris(trimethylsiloxy)silyl group monomers, wherein the polymer has a weight average molecular weight (Mw) of 5,000 to 200,000 daltons, and an organic solvent;
immersing the barrier coating layer in an immersion medium;
transmitting ultraviolet radiation to the photoresist layer through the immersion medium and the barrier coating layer to form an exposed photoresist layer;
removing the barrier layer; and
developing the exposed photoresist layer.

16. The method of forming a photoresist pattern according to claim 15, further comprising:
soft-baking the photoresist layer before forming the barrier coating layer;
evaporating a majority of the solvent from the barrier coating material to form the barrier coating layer; and
post-exposure baking the exposed photoresist layer before removing the barrier coating layer.

17. The method of forming a photoresist pattern according to claim 15, wherein forming the barrier coating layer includes:
depositing a quantity of the barrier coating composition on the photoresist layer;
distributing the barrier coating composition across the upper surface of the photoresist layer; and
solidifying the distributed barrier coating composition to form the barrier coating layer.

18. The method of forming a photoresist pattern according to claim 17, wherein distributing the barrier coating composition across the upper surface of the photoresist layer includes:
spinning the substrate at 500 to 3000 rpm and maintaining this rotation for 30 to 90 seconds after depositing the quantity of the barrier coating composition on the upper surface of the photoresist layer; and
heating the distributed barrier coating to a heat treatment temperature in a range from 95° C. to 120° C. to form the barrier coating layer.

19. The method of forming a photoresist pattern according to claim 15, wherein removing the barrier coating layer and developing the exposed photoresist layer include:
applying a single developing solution to remove both the barrier coating layer and at least a portion of the exposed photoresist layer.

20. The method of forming a photoresist pattern according to claim 15, wherein removing the barrier coating layer and developing the exposed photoresist layer include:
applying first developing solution to remove the barrier coating layer; and
applying a second developing solution to remove at least a portion of the exposed photoresist layer.

21. The method of forming a photoresist pattern according to claim 20, wherein:
the single developing solution is an alkaline developing solution.

22. The method of forming a photoresist pattern according to claim 15, wherein:
the ultraviolet radiation has a wavelength selected from a group consisting of 248 nm, 193 nm and 157 nm.

23. The method of forming a photoresist pattern according to claim 15, wherein:
the polymer corresponds to formula I: 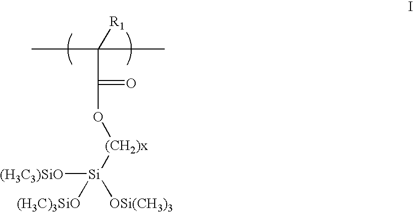
wherein R₁ is selected from a group consisting of hydrogen, methyl and mixtures thereof; and
x is at least one integer from 2 to 6.

24. The method of forming a photoresist pattern according to claim 23, wherein:
the polymer includes a plurality of second monomers wherein each of the second monomers includes a polar group.

25. The method of forming a photoresist pattern according to claim 24, wherein:
the polar groups are selected from a group consisting of alcohols, acids and combinations thereof.

26. The method of forming a photoresist pattern according to claim 25, wherein:
the polymer corresponds to formula II: 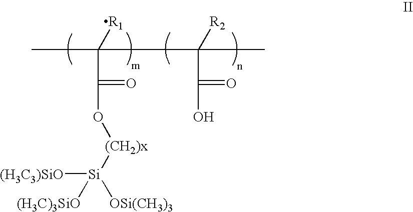
wherein R₁ and R₂ are independently selected from a group consisting of hydrogen, methyl and mixtures thereof;
x is an integer from 2 to 6; and
the expressions (m+n)=1 and 0.1≦(m/(m+n))≦0.9 are satisfied.

27. The method of forming a photoresist pattern according to claim 25, wherein:
the second monomers include an acid anhydride.

28. The method of forming a photoresist pattern according to claim 25, wherein:
the polymer also includes a third monomer selected from a group consisting of acrylates and methacrylates.

29. The method of forming a photoresist pattern according to claim 27, wherein:
the polymer corresponds to formula III: 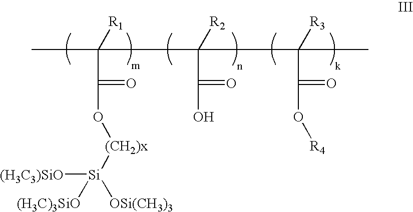
where R₁, R₂ and R₃ are independently selected from a group consisting of hydrogen and methyl;
R₄ is selected from a group consisting of C₁ to C₁₀ alkyl, aldehyde, hydroxyalkyl, allyl acid and amino groups;
x is an integer from 2 to 6;
and the expressions
(m+n+k)=1;
0.1≦(m/(m+n+k))≦0.8;
0.1≦(n/(m+n+k))≦0.8; and
0.1≦(k/(m+n+k))≦0.8 are satisfied.

30. The method of forming a photoresist pattern according to claim 28, wherein:
R₄ is a hydroxyethyl group.

31. The method of forming a photoresist pattern according to claim 15, wherein:
the organic solvent is selected from a group consisting of alcohol-based organic solvents, alkane-based organic solvents and combinations thereof.

32. The method of forming a photoresist pattern according to claim 31, wherein:
the organic solvent is selected from a group consisting of C₃ to C₁₀ alcohol-based organic solvents, C₄ to C₁₂ alkane-based organic solvents and combinations thereof.

33. The method of forming a photoresist pattern according to claim 15, wherein:
the organic solvent includes an alcohol-based organic solvent and at least one additional material selected from a group consisting of alkanes, nitryls, ethers, viscosity modifiers and surfactants.
